(19) United States
(12) Patent Application Publication
(10) Pub. No.: US 2020/0166438 A1
(43) Pub. Date: May 28, 2020

(54) TISSUE MARKING SYSTEM

(71) Applicant: Clear-Cut Medical Ltd., Rehovot (IL)

(72) Inventor: Armin Schon, Nes Ziona (IL)

(73) Assignee: Clear-Cut Medical Ltd., Rehovot (IL)

(21) Appl. No.: 16/636,714

(22) PCT Filed: Aug. 2, 2018
(86) PCT No.: PCT/IB2018/055804

§ 371 Date: Feb. 5, 2020

Related U.S. Application Data
(60) Provisional application No. 62/546,631, filed on Aug. 17, 2017.

(51) Int. Cl. G01N 1/31; C23C 14/04; C23C 14/28; G01N 35/00

(52) U.S. Cl. CPC G01N 1/31; C23C 14/048; G01N 2001/282; G01N 35/00732; C23C 14/28

(57) ABSTRACT

A marking system (10) includes a tissue holder (14) which has a cover (16). An inner surface of the cover (16) is coated with a donor layer (18). A pulsed laser (20) emits a laser pulse sufficient to transfer material from the donor layer (18) onto tissue (12) held in the tissue holder (14) by means of a laser-induced forward transfer (LIFT) technique, and the material transferred to the tissue (12) creates a mark on the tissue (12).

### FIELD OF THE INVENTION

The present invention relates generally to a system and a method for marking tissue samples, such as marking areas suspected of containing pathologically irregular or abnormal cells.

### BACKGROUND OF THE INVENTION

In checking whether a tissue contains cancerous cells, a tissue sample containing the suspicious cells is removed from an organ of a patient for further investigation (e.g., biopsy or margin assessment investigation).

For example, pathological inspection of tissue removed during breast conserving surgery (BCS) can be achieved with a process called frozen section, by which the excised tissue is frozen to make it mechanically suitable for slicing. These slices are removed at several locations and inspected under a conventional light microscope. Post-operative histopathology of tissue is also done to investigate if cancerous cells remain on the surface of the excised tissue.

However, this is a microscopic investigation of a macroscopic object (lump of excised tissue). This kind of investigation takes a long time because there is no prior knowledge of where to look for the microscopic cells in the macroscopic object. Alternatively, if there is a time constraint put upon the investigation, only a small part of the surface can be inspected through sampling.

A magnetic resonance imaging (MRI) system can be used to provide knowledge of where to look for the microscopic cells in the macroscopic object. For example, the CLEARSIGHT system (commercially available from ClearCut Medical Ltd., Israel) can be used to display images of the tissue, mapped with pixels, such as in the form of diffusion weighted parameter maps. Suspicious pixels can be marked so that further microscopic investigation is performed only on these pixels, thereby significantly reducing the investigation time and improving the probability that the clinically most relevant portions of the surface are being inspected microscopically, thereby improving the diagnostic accuracy of the investigation. The MRI system can guide the pathologist, to the suspicious areas on the surface of the excised lump, both for the intra-operative frozen section pathological examination, and even more so for final, post-operative histopathology.

However, the marking of the pixels in the MRI system is done when the tissue is fresh and has not yet been processed. A problem is that when the pathologist takes tissue blocks for slicing, the tissue is either frozen (for example, a frozen section in the operating room) or stabilized in formalin and paraffin for final histopathology and long-term archiving. Both the freezing and stabilizing processes deform the lump and change its colors, making it difficult to identify the suspicious spots (pixels) that had been marked (tagged, highlighted, colored and the like) on the digital images provided by the MRI system when the tissue was fresh.

### SUMMARY OF THE INVENTION

The present invention seeks to provide improved systems and methods for marking suspicious spots (e.g., pixels) on a tissue sample such that the marking is preserved throughout the tissue processing (e.g., freezing or stabilizing) and remains detectable (e.g., human visible or machine detectable) to the pathologist even after processing, as is describe in detail hereinbelow.

There is provided in accordance with a non-limiting embodiment of the invention a marking system including a tissue holder which has a cover, wherein an inner surface of the cover is coated with a donor layer, and a pulsed laser configured to emit a laser pulse sufficient to transfer material from the donor layer onto tissue held in the tissue holder by means of a laser-induced forward transfer (LIFT) technique, part of the material transferred to the tissue creating a mark on the tissue.

In accordance with a non-limiting embodiment of the invention the laser pulse is sufficient to vaporize material from the donor layer and the material condenses on the tissue. Alternatively, the laser pulse is sufficient to transfer material from the donor layer without vaporizing the material.

In accordance with a non-limiting embodiment of the invention the donor layer includes at least one of a visible or fluorescent ink, a paste, a polymer, a metal, a quantum dot and a nanoparticle. The materials may be embedded in a carrier material, which absorbs the energy of the laser pulse and melts or evaporates, thereby transferring the material to the substrate without changing the material itself. Such carrier layers can be of solid or paste-like consistency.

In accordance with a non-limiting embodiment of the invention the donor layer is transparent in the visible spectrum, such that the substrate (tissue) surface can be observed through the glass cover by means of a camera or by the unaided eye of an observer.

In accordance with a non-limiting embodiment of the invention the pulsed is configured to operate in a wavelength range of 100-700 nm with an energy thence of 40-100 mJ/cm² and pulse duration of 0.001-100 μsec.

In accordance with a non-limiting embodiment of the invention a method for marking includes using the system to emit a laser pulse sufficient to transfer material from the donor layer onto the tissue held in the tissue holder by means of LIFT.

### BRIEF DESCRIPTION OF THE DRAWINGS

The present invention will be understood and appreciated more fully from the following detailed description, taken in conjunction with the drawings in which:

FIG. 1 is a simplified illustration of a tissue marking system, constructed and operative in accordance with a non-limiting embodiment of the present invention.

### DETAILED DESCRIPTION OF EMBODIMENTS

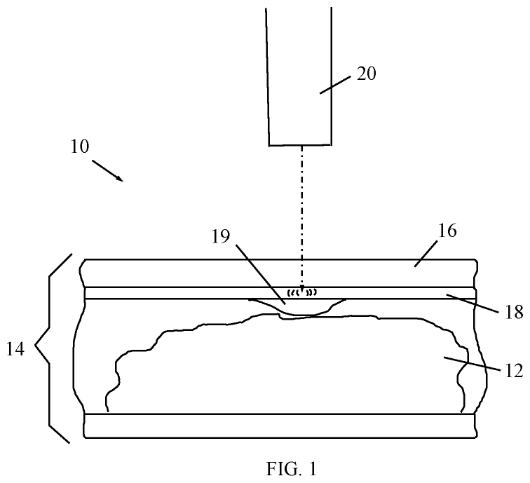

Reference is now made to FIG. 1, which illustrates a tissue marking system 10, constructed and operative in accordance with a non-limiting embodiment of the present invention.

In one embodiment, a tissue sample 12 is held in a tissue holder 14 which has a transparent or translucent cover 16 (e.g., a glass cover). An example of a suitable tissue sample holder 14 is the CLEARPACK tissue holder, commercially available from ClearCut Medical Ltd., Israel. This tissue holder is constructed of MR inert materials and is transparent. In this embodiment, the CLEARPACK tissue holder is modified in that the inner surface of cover 16 is coated with a donor layer 18 for creating a location marker, which is transferred from the cover 16 onto the tissue 12 right after the imaging scan (such as an MRI scan; but the invention can be carried out with other imaging techniques, such as x-ray) before the tissue 12 is removed from the tissue holder 14. In one embodiment the mark is made with laser-induced forward transfer (LIFT) techniques.

LIFT is a direct-writing technique that allows depositing tiny amounts of material from a thin film (e.g., deposited onto a transparent holder) to a receptor substrate by means of a laser pulse. The technique was initially developed to transfer inorganic materials from precursor solid films. The laser pulse completely vaporizes a small portion of the solid film and the vapor condenses onto the receptor substrate as a marking (e.g., a solid dot). LIFT has also been developed to transfer materials that are in the form of a paste or liquid. Instead of being vaporized, a small volume of paste or liquid is directly ejected from the holder under the action of the laser pulse, and the material preserves its paste or liquid nature once deposited onto the receptor substrate

Accordingly, a pulsed laser 20 may emit a laser pulse to heat and evaporate the coating material (donor layer) 18, thereby transferring the coating material 18 from cover 16 and depositing transferred material 19 onto the tissue 12 at the precise location which is required to be marked. The tissue 12 may be in direct, mechanical contact with the donor layer 18. The gap shown in FIG. 1 is not necessarily required.

Materials suitable for printing include, without limitation, visible or fluorescent ink, pastes, polymers, metals, quantum dots, nanoparticles, or any other material that will evaporate from the tissue holder cover, whereupon the vapor will condense and adhere to the tissue (which is usually wet, but could also be dry) to create the desired mark, or pastes or liquids which can be transferred without evaporation.

Different lasers and pulse parameters may be used to carry out the invention. Without limitation, lasers in the wavelength range of 100-700 nm with an energy fluence of 40-100 mJ/cm² and pulse duration in the range of 0.001-100 μsec may be used.

In one embodiment, even with the coating 18, the cover 16 is still transparent or close to transparent, which permits visual inspection of the tissue 12 held in the holder 14. In such an embodiment, the coating may be very thin, which in turn means that not a lot of material is transferred and it may be difficult to see the marking with the naked eye. In such a case, it may be advantageous to use fluorescent materials, quantum dots and nanoparticles and the like, which emit strong optical responses when excited with a UV light source or a laser of a particular wavelength, therefore providing good visual or machine detectability despite the small quantity of material printed onto the tissue.

The marking process and device of the invention may be used to mark suspicious spots (e.g., pixels) on the tissue sample, wherein the marking is preserved throughout the tissue processing (e.g., freezing or stabilizing) and remains detectable (e.g., human visible or machine detectable) to the pathologist even after processing.

The laser device and/or the tissue holder may be moved to align the laser pulse with the area to be marked, such as by means of an actuator, step motor, x-y-z moving table and the like.

What is claimed is:

1. A marking system (10) comprising:
a tissue holder (14) which has a cover (16), wherein an inner surface of said cover (16) is coated with a donor layer (18); and
a pulsed laser (20) configured to emit a laser pulse sufficient to transfer material from said donor layer (18) onto tissue (12) held in said tissue holder (14) by means of a laser-induced forward transfer (LIFT) technique, said material transferred to the tissue (12) creating a mark on the tissue (12).

2. The marking system (10) according to claim 1, wherein said laser pulse is sufficient to vaporize material from said donor layer (18) and said material condenses on the tissue (12).

3. The marking system (10) according to claim 1, wherein said laser pulse is sufficient to transfer material from said donor layer (18) without vaporizing the material.

4. The marking system (10) according to claim 1, wherein said donor layer (18) comprises at least one of a visible or fluorescent ink, a paste, a polymer, a metal, a quantum dot and a nanoparticle.

5. The marking system (10) according to claim 1, wherein said pulsed laser (20) is configured to operate in a wavelength range of 100-700 nm with an energy fluence of 40-100 mJ/cm² and pulse duration of 0.001-100 μsec.

6. A method for marking comprising using said system of claim 1, comprising emitting a laser pulse sufficient to transfer material from said donor layer (18) onto the tissue (12) held in said tissue holder (14) by means of LIFT.
